(19) United States
(12) Patent Application Publication
(10) Pub. No.: US 2012/0248610 A1
(43) Pub. Date: Oct. 4, 2012

(54) SEMICONDUCTOR MEMORY DEVICE AND METHOD OF FABRICATING THE SAME

(75) Inventor: Fumie KIKUSHIMA, Mie-ken (JP)

(73) Assignee: Kabushiki Kaisha Toshiba, Tokyo (JP)

(21) Appl. No.: 13/424,802

(22) Filed: Mar. 20, 2012

(30) Foreign Application Priority Data
Mar. 31, 2011 (JP) 2011-080241

(51) Int. Cl. H01L 23/52; H01L 21/768

(52) U.S. Cl. 257/751; 438/642; 257/E21.575; 257/E23.141

(57) ABSTRACT

According to one embodiment, a semiconductor memory device comprises: a semiconductor substrate; a first contact plug and a second contact plug on the semiconductor substrate; a first bit line being in contact with the first contact plug; and a second bit line on the second contact plug, wherein the first contact plug is in contact with a top surface of the first bit line and is electrically insulated from the second bit line, and a bottom surface of the second bit line is higher in height than the top surface of the first bit line.

### FIELD

Embodiments described herein relate generally to a semiconductor memory device and a method of fabricating the same.

### BACKGROUND

In recent years, there have been advancements in miniaturization of memory cells in NAND non-volatile semiconductor memory devices. With the miniaturization of memory cells, circuit wirings such as bit lines are becoming finer and finer, which makes the wirings closer to each other. For this reason, there have been problems of an increased coupling capacitance between the adjacent wirings and a decreased withstand voltage between the wirings. To address these problems, a technique may be employed in which the adjacent bit lines are provided respectively in two layers, namely, an upper layer and a lower layer so that the distance between the bit lines can be increased. By this technique, the above problems can be alleviated. However, in the bit-line arrangement with the two-layer structure, contact plugs connected to the bit lines in the upper layer and the lower layer need to be formed, and therefore their contact holes needs to be processed in separate steps. This causes a problem that the number of fabrication steps increases.

### BRIEF DESCRIPTION OF THE SEVERAL VIEWS OF THE DRAWING

FIG. 1 is a plan view showing a bit-line arrangement in a semiconductor memory device according to an embodiment.

FIGS. 2A and 2B are cross-sectional views showing the semiconductor memory device according to the embodiment. FIG. 2A shows a cross-sectional view taken along the A-A′ line in FIG. 1, while FIG. 2B shows a cross-sectional view taken along the B-B′ line in FIG. 1.

FIGS. 3A and 3B are cross-sectional views showing a method of fabricating the semiconductor memory device according to the embodiment. FIG. 3A shows a cross-sectional view taken along the A-A′ line in FIG. 1, while FIG. 3B shows a cross-sectional view taken along the B-B′ line in FIG. 1.

FIGS. 4A and 4B are cross-sectional views showing the method of fabricating the semiconductor memory device according to the embodiment. FIG. 4A shows a cross-sectional view taken along the A-A′ line in FIG. 1, while FIG. 4B shows a cross-sectional view taken along the B-B′ line in FIG. 1.

FIGS. 5A and 5B are cross-sectional views showing the method of fabricating the semiconductor memory device according to the embodiment. FIG. 5A shows a cross-sectional view taken along the A-A′ line in FIG. 1, while FIG. 5B shows a cross-sectional view taken along the B-B′ line in FIG. 1.

FIGS. 6A and 6B are cross-sectional views showing the method of fabricating the semiconductor memory device according to the embodiment. FIG. 6A shows a cross-sectional view taken along the A-A′ line in FIG. 1, while FIG. 6B shows a cross-sectional view taken along the B-B′ line in FIG. 1.

FIGS. 7A and 7B are cross-sectional views showing the method of fabricating the semiconductor memory device according to the embodiment. FIG. 7A shows a cross-sectional view taken along the A-A′ line in FIG. 1, while FIG. 7B shows a cross-sectional view taken along the B-B′ line in FIG. 1.

FIGS. 8A and 8B are cross-sectional views showing the method of fabricating the semiconductor memory device according to the embodiment. FIG. 8A shows a cross-sectional view taken along the A-A′ line in FIG. 1, while FIG. 8B shows a cross-sectional view taken along the B-B′ line in FIG. 1.

FIGS. 9A and 9B are cross-sectional views showing the method of fabricating the semiconductor memory device according to the embodiment. FIG. 9A shows a cross-sectional view taken along the A-A′ line in FIG. 1, while FIG. 9B shows a cross-sectional view taken along the B-B′ line in FIG. 1.

### DETAILED DESCRIPTION OF THE INVENTION

A semiconductor memory device of an embodiment includes a semiconductor substrate. First contact plugs and second contact plugs are provided on the semiconductor substrate. First bit lines are provided in contact with the first contact plugs, respectively. Second bit lines are provided on the second contact plugs, respectively. Each first contact plug is in contact with the top surface of its corresponding first bit line and is electrically insulated from each second bit line. The bottom surface of the second bit line is higher in height than the top surface of the first bit line.

Hereinbelow an embodiment of the present invention will be described by referring to the drawings.

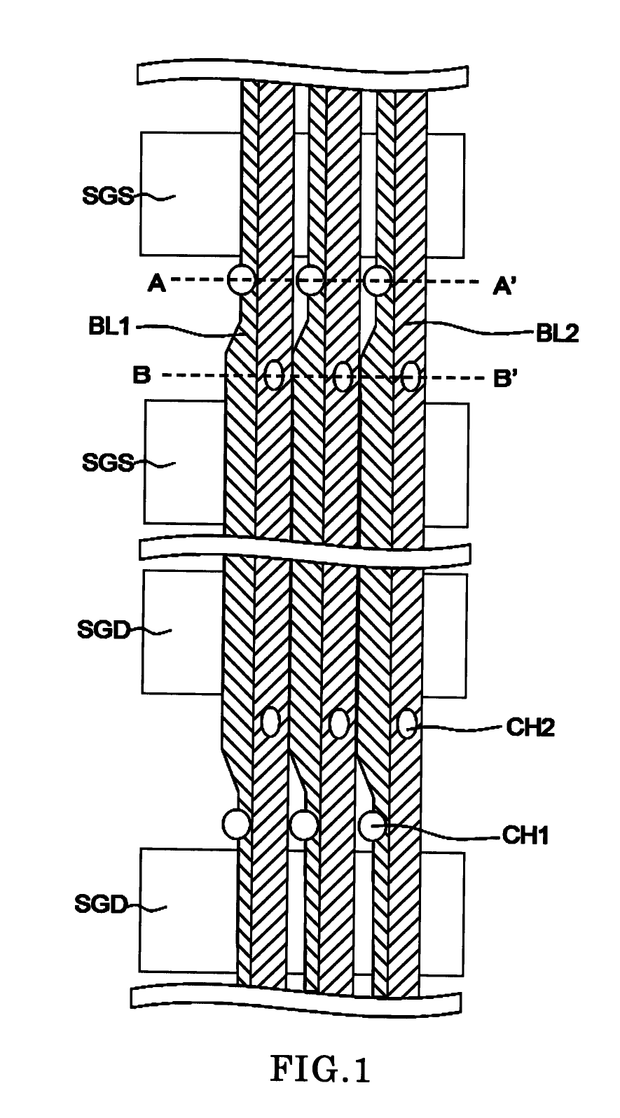

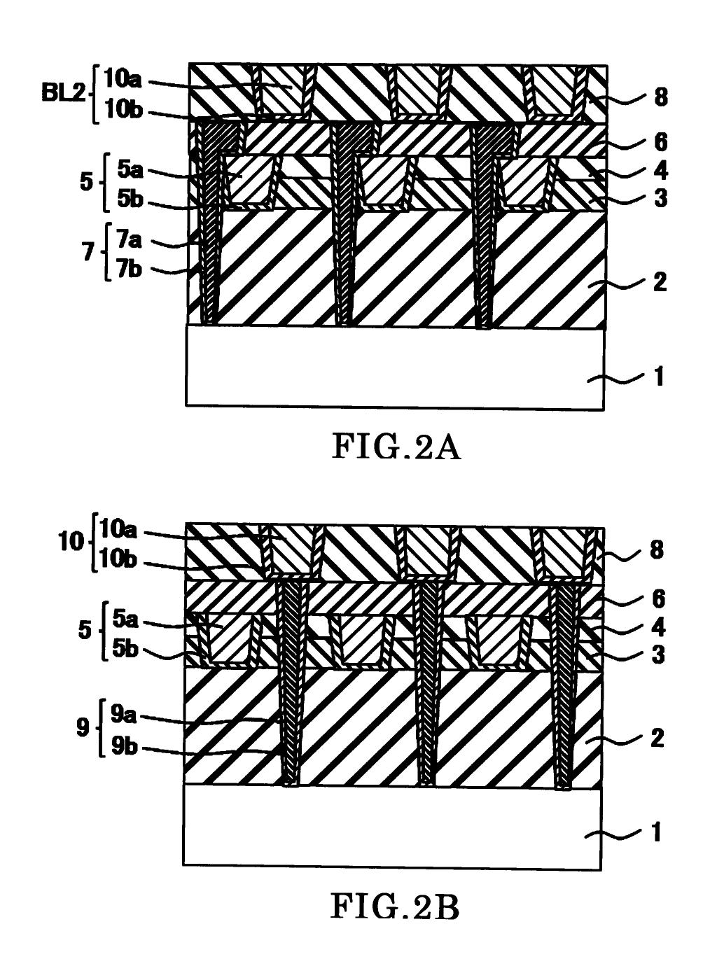

FIG. 1 shows a plan view of a bit-line arrangement in a semiconductor memory device of the embodiment. FIGS. 2A and 2B are cross-sectional views showing the semiconductor memory device of the embodiment. FIG. 2A shows a cross-sectional view taken along the A-A′ line in FIG. 1, while FIG. 2B shows a cross-sectional view taken along the B-B′ line in FIG. 1.

As shown in FIGS. 1 to 2B, a source-side select gate SGS and a drain-side select gate SGD are provided, and memory cells are provided between the select gate SGS and the select gate SGD. First bit lines BL1 are connected to a semiconductor substrate 1 through later-described first contact plugs 7, respectively. Second bit lines BL2 are connected to the semiconductor substrate 1 through later-described second contact plugs 9, respectively. The first bit lines BL1 and the second bit lines BL2 extend in a first direction which is substantially perpendicular to a second direction. The first direction refers to the direction in which the second bit lines BL2 extend. Moreover, the second direction refers to the direction which is substantially perpendicular to the first direction in the plan view of FIG. 1.

In a region along the A-A′ line in the plan view of FIG. 1, the first bit lines BL1 and the second bit lines BL2 are provided alternately in the second direction, for example. In a region along the A-A′ line in the plan view of FIG. 1 where the first bit lines BL1 intersect their respective first contact holes CH1, the first bit lines BL1 are each shifted in the second direction by a distance substantially equal to the half the diameter of the top surface of the first contact hole CH1.

The first contact holes CH1 and the second contact holes CH2 are each designed to be connected to a source layer (unillustrated) or a drain layer (unillustrated) provided on the surface of the semiconductor substrate 1. FIG. 1 shows an example where the first contact holes CH1 and the contact holes CH2 are each connected to a drain layer.

In a region along the B-B′ line in the plan view of FIG. 1, the first bit lines BL1 and the second bit lines BL2 are provided alternately in the second direction, for example.

The first bit lines BL1 and the second bit lines BL2 are electrically insulated from each other. As shown in FIGS. 2A and 2B, the bottom surfaces of the second bit lines BL2 are higher in height than the top surfaces of the first bit lines BL1. In other words, provided is a two-layer wiring structure in which the first bit lines BL1 are the lower-layer wirings and the second bit lines BL2 are the upper-layer wirings.

As shown in FIGS. 2A and 2B, a first interlayer insulating film 2 is provided on the semiconductor substrate 1. As the first interlayer insulating film 2, a TEOS film, a BPSG film, or a silicon oxide film is used, for example.

A first stopper film 3 is provided on the first interlayer insulating film 2. The first stopper film 3 is used to stop etching performed in the formation of later-described first wiring trenches 12 for forming the first bit lines BL1. For the first stopper film 3, a material differing in RIE etch selectivity from the first interlayer insulating film 2 is used. A silicon nitride film is used, for example.

A second interlayer insulating film 4 is provided on the first stopper film 3. As the second interlayer insulating film 4, a TEOS film, a BPSG film, or a silicon oxide film is used, for example, as in the case of the first interlayer insulating film 2.

The first bit lines BL1 extending in the first direction are provided on the first interlayer insulating film 2 inside the first stopper film 3 and the second interlayer insulating film 4. In the region along the A-A′ line in the plan view of FIG. 1 where the first bit lines BL1 intersect with their respective first contact plugs 7, the first bit lines BL1 are shifted in the second direction by the distance substantially equal to the half the diameter of the top surface of the first contact hole CH1, from their positions in the region along the B-B′ line in FIG. 1.

Note that the shifted distance is not limited to the distance substantially equal to the half the diameter of the top surface of the first contact hole CH1, as long as the first bit lines BL1 are not shifted by a distance greater than the diameter of the top surface of the first contact hole CH1. The first bit lines BL1 are provided at periodic intervals in the second direction. The diameter of the top surface of the first contact hole CH1 refers to “diameter” when the shape of the top surface is circular for example, and when elliptical, refers to the length of a line segment passing through the center of the ellipse and connecting the opposing ends, in the second direction, of the ellipse.

Meanwhile, when having a tapered shape, the first bit lines BL1 may serve as masks during the formation of the first contact holes CH1, thereby possibly blocking the etching of portions of the first stopper film 3 and the second interlayer insulating film 4 in contact with the side surfaces of the first bit lines BL1. For this reason, the cross-sectional shape of the portion of each first bit line BL1 in contact with the first stopper film 3 and the second interlayer insulating film 4 should desirably be substantially rectangular with a small inclination and more desirably completely rectangular, instead of being tapered. Being substantially rectangular means that a tapered angle is 85 degrees or larger where the tapered angle is an acute angle formed between the side surface of the first bit line BL1 and the interface between the first interlayer insulating film 2 and the first bit line BL1.

Each first bit line BL1 is formed of a wiring layer 5a extending in the first direction and a barrier metal film 5b covering the bottom and side surfaces thereof, for example. As the wiring layer 5a, a Cu layer is used, for example. As the barrier metal film 5b, a conductive film such as a single layer film using Ti, TiN, or the like or a stacked film using Ti and TiN is used, for example.

A second stopper film 6 is provided on the first bit lines BL1 and the second interlayer insulating film 4. The second stopper film 6 is used to stop etching performed in the formation of later-described second wiring trenches 15 for forming the second bit lines BL2. For the second stopper film 6, a material differing in RIE etch selectivity from the second interlayer insulating film 4 is used, as in the case of the first stopper film 3. A silicon nitride film is used, for example.

As shown in FIG. 2A, on the semiconductor substrate 1, the first contact plugs 7 are provided penetrating the first interlayer insulating film 2, the first stopper film 3, the second interlayer insulating film 4, and the second stopper film 6. As shown in FIG. 2A, each first contact plug 7 is not connected to the bottom surface of its corresponding first bit line BL1 but is connected to part of the top surface of the first bit line BL1. The first contact plug 7 may further be connected to the side surface of the first bit line BL1. In this case, the area of the contact between the first contact plug 7 and the first bit line BL1 is greater than a conventionally used configuration in which the bottom surface of the bit line is connected to the top surface of the contact plug. Accordingly, the electrical reliability can be maintained at a preferable level.

Each first contact plug 7 is formed by using a tungsten film serving as a contact plug layer 7a and a barrier metal film 7b covering the tungsten film, for example. As the barrier metal film 7b, a conductive film such as a single layer film using Ti, TiN, or the like or a stacked film using Ti and TiN is used, for example.

A third interlayer insulating film 8 is provided on the first contact plugs 7 and the second stopper film 6. As the third interlayer insulating film 8, a TEOS film, a BPSG film, or a silicon oxide film is used, for example, as in the cases of the first interlayer insulating film 2 and the second interlayer insulating film 4.

The second bit lines BL2 extending in the first direction are provided on the second stopper film 6 inside the third interlayer insulating film 8. Each second bit line BL2 is formed of a wiring layer 10a extending in the first direction and a barrier metal film 10b covering the bottom and side surfaces thereof, for example. As the wiring layer 10a, a Cu layer is used, for example. As the barrier metal film 10b, a conductive film such as a single layer film using Ti, TiN, or the like or a stacked film using Ti and TiN is used, for example. The width of each second bit line BL2 is substantially equal to the width of each first bit line BL1.

As shown in FIG. 2B, on the semiconductor substrate 1, the second contact plugs 9 are provided penetrating the first interlayer insulating film 2, the first stopper film 3, the second interlayer insulating film 4, and the second stopper film 6. As shown in FIG. 2B, each second contact plug 9 is connected to the bottom surface of its corresponding second bit line BL2.

Each second contact plug 9 is formed by using a tungsten film serving as a contact plug layer 9a and a barrier metal film 9b covering the tungsten film, for example. As the barrier metal film 9b, a conductive film such as a single layer film using Ti, TiN, or the like or a stacked film using Ti and TiN is used, for example.

As shown in FIG. 1, the first contact plugs 7 and the second contact plugs 9 are arranged alternately in a periodic pattern in the second direction at an interval equal to the width of each first bit line BL1 or second bit line BL2. The first contact plugs 7 and the second contact plugs 9 together form a staggered structure. This structure secures a longer distance between the first bit line BL1 and the second bit line BL2 than when the first contact plugs 7 and the second contact plugs 9 are aligned in a straight line in the second direction. Accordingly, the leak current and parasitic capacitance between the wirings can be reduced.

In the embodiment, the diameter of the bottom surface of each first contact plug 7 is substantially equal to that of the bottom surface of each second contact plug 9. The diameter of the top surface of the second contact plug 9 is substantially the half the diameter of the top surface of the first contact plug 7.

In the embodiment, the height of each first contact plug 7 is substantially equal to that of each second contact plug 9.

In the semiconductor memory device according to the embodiment, each first contact plug 7 is connected to the top surface of its corresponding first bit line BL1. Accordingly, the electrical reliability of the first contact plug 7 and the first bit line BL1 can be maintained at a preferable level.

In a case where the first contact plug 7 is further connected to the side surface of the first bit line BL1, the area of the contact between the first contact plug 7 and the first bit line BL1 increases, thereby improving the electrical reliability.

Hereinbelow, a method of fabricating the semiconductor memory device according to the embodiment will be described using drawings.

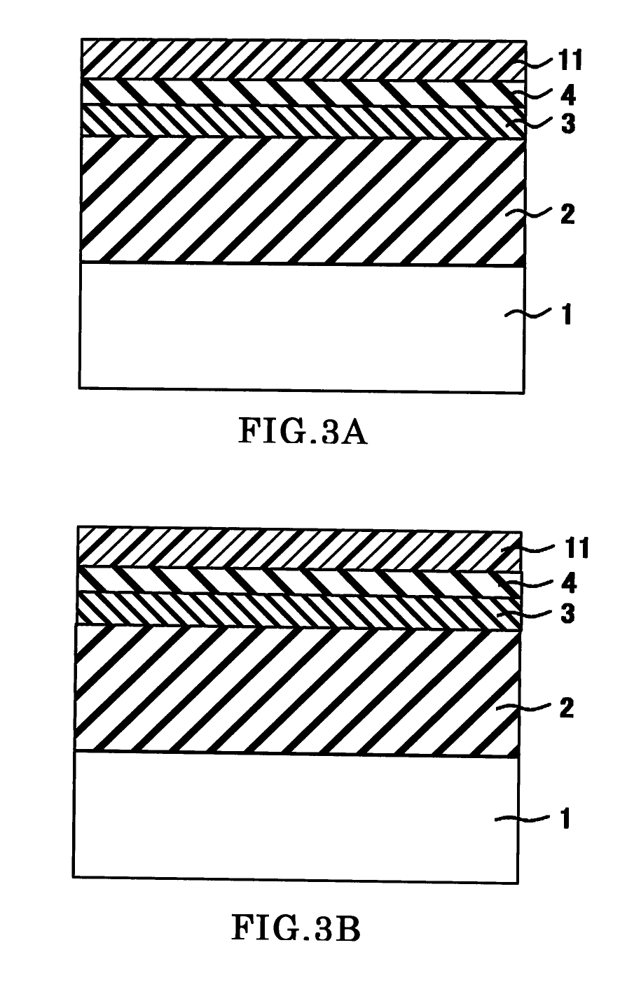

FIGS. 3A to 9B are cross-sectional views showing the method of fabricating the semiconductor memory device according to the embodiment, the cross-sectional views being normal to the bit-line direction.

As shown in FIGS. 3A and 3B, a TEOS film for example is formed as the first interlayer insulating film 2 on the semiconductor substrate 1 by CVD. Then, a silicon nitride film for example is formed as the first stopper film 3 on the first interlayer insulating film 2 by CVD. Then, a TEOS film for example is formed as the second interlayer insulating film 4 on the first stopper film 3 by CVD. Thereafter, a photoresist film 11 is formed on the second interlayer insulating film 4 by coating.

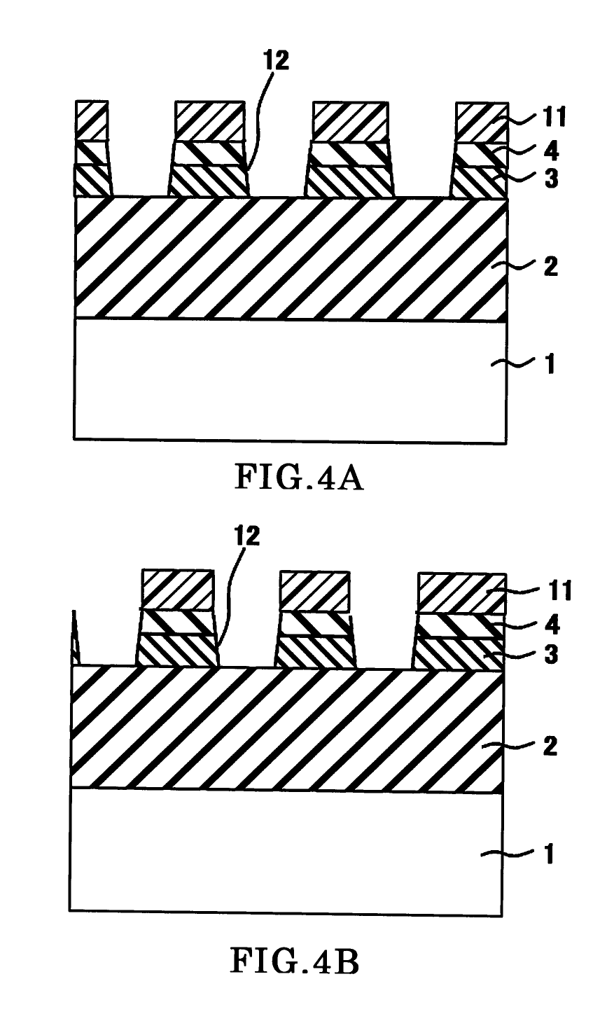

Subsequently, as shown in FIGS. 4A and 4B, the photoresist film 11 is processed through exposure, development, and the like steps in photolithography, and the second interlayer insulating film 4 is etched by RIE by using the processed photoresist film 11 as a mask.

Then, the first stopper film 3 is etched to form the first wiring trenches 12 for forming the first bit lines BL1. The first wiring trenches 12 are processed such that the first bit lines BL1 can extend in the first direction and be formed at the periodic intervals in the second direction. Further, in the region where the first bit lines BL1 intersect the later-mentioned first contact holes CH1, the first wiring trenches 12 are formed such that they are shifted in the second direction by a distance substantially equal to the half the diameter of the top surface of each first contact hole CH1. Note that the shifted distance is not limited to the distance substantially equal to the half the diameter of the top surface of the first contact hole CH1.

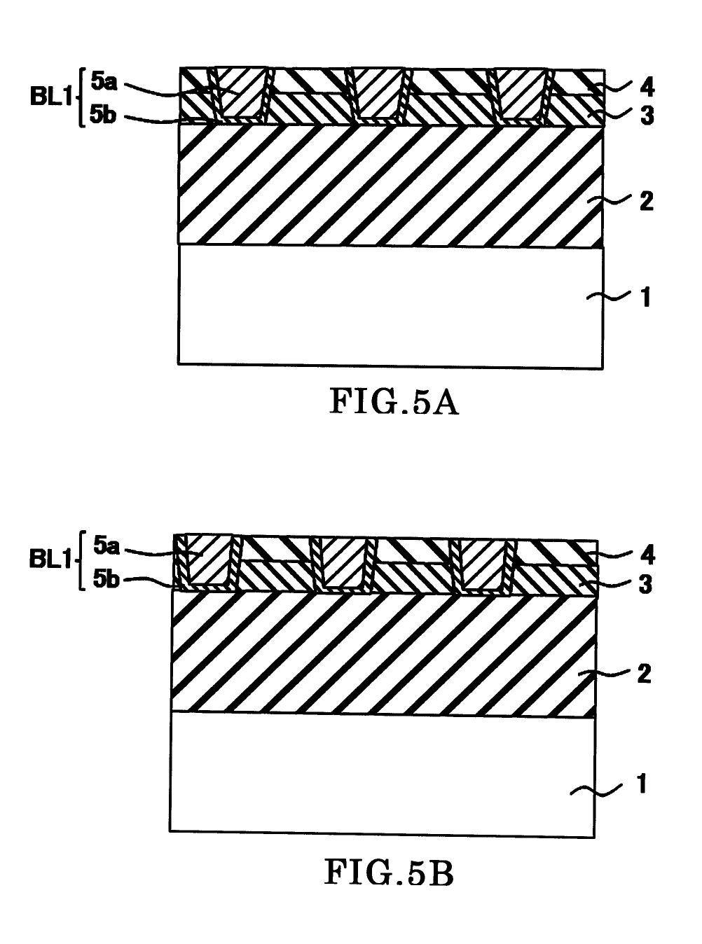

Subsequently, as shown in FIGS. 5A and 5B, after the photoresist film 11 is removed, a Ti/TiN stacked film is formed as the barrier metal film 5b in the first wiring trenches 12, and a Cu wiring is formed as the wiring layer 5a on the barrier metal film 5b. Then, the Cu wiring, or the wiring layer 5a, and the Ti/TiN stacked film, or the barrier metal film 5b, on the second interlayer insulating film 4 are polished by CMP, whereby the first bit lines BL1 are formed.

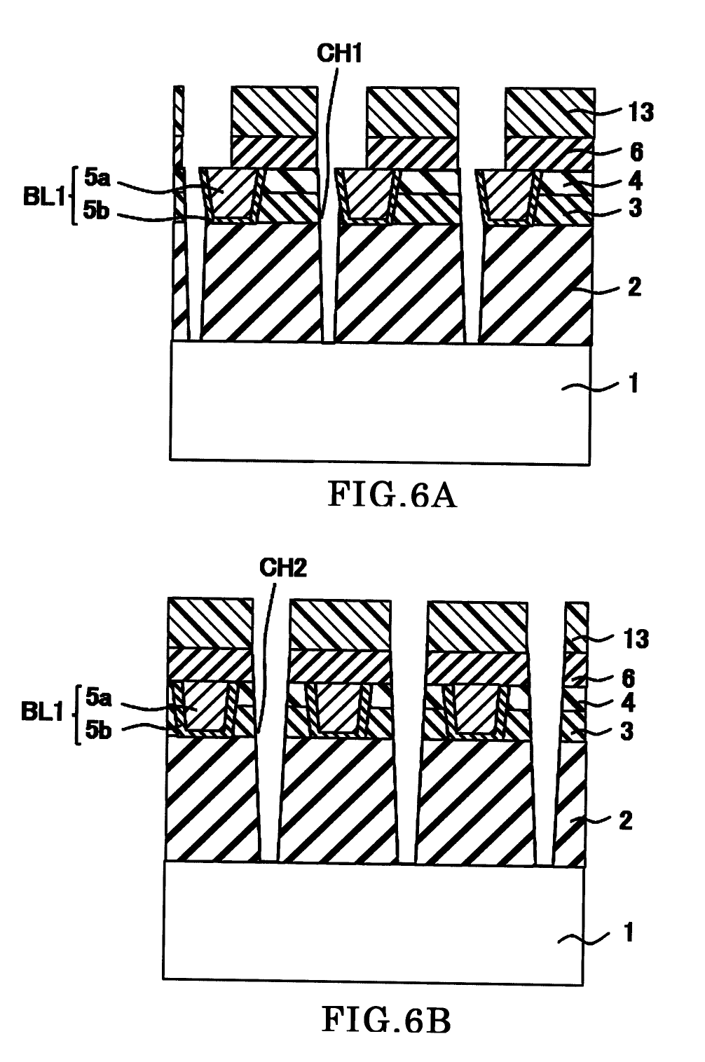

Subsequently, as shown in FIGS. 6A and 6B, a silicon nitride film for example is formed as the second stopper film 6 on the first bit lines BL1 and the second interlayer insulating film 4. Then, a photoresist film 13 is formed on the second stopper film 6. Then, the photoresist film 13 is processed through exposure, development, and the like steps in photolithography.

Then, the second interlayer insulating film 4, the first stopper film 3, and the first interlayer insulating film 2 are etched by RIE until the semiconductor substrate 1 is exposed. As a result, as shown in FIGS. 1, 6A, and 6B, the top surfaces of the first bit lines BL1 are exposed, and also the first contact holes CH1 and the second contact holes CH2 are formed. In this step, a substantially half area of the top surface of each first contact plug 7 becomes exposed, for example. Moreover, in the first contact hole CH1, the side surface of the first bit line BL1 is desirably exposed. In the embodiment, the height of each first contact hole CH1 is substantially equal to that of each second contact hole CH2.

Thereafter, the photoresist film 13 is removed.

As shown in FIG. 1, the first contact holes CH1 and the second contact holes CH2 are each formed to be arranged at periodic intervals in the second direction and also arranged in a staggered pattern.

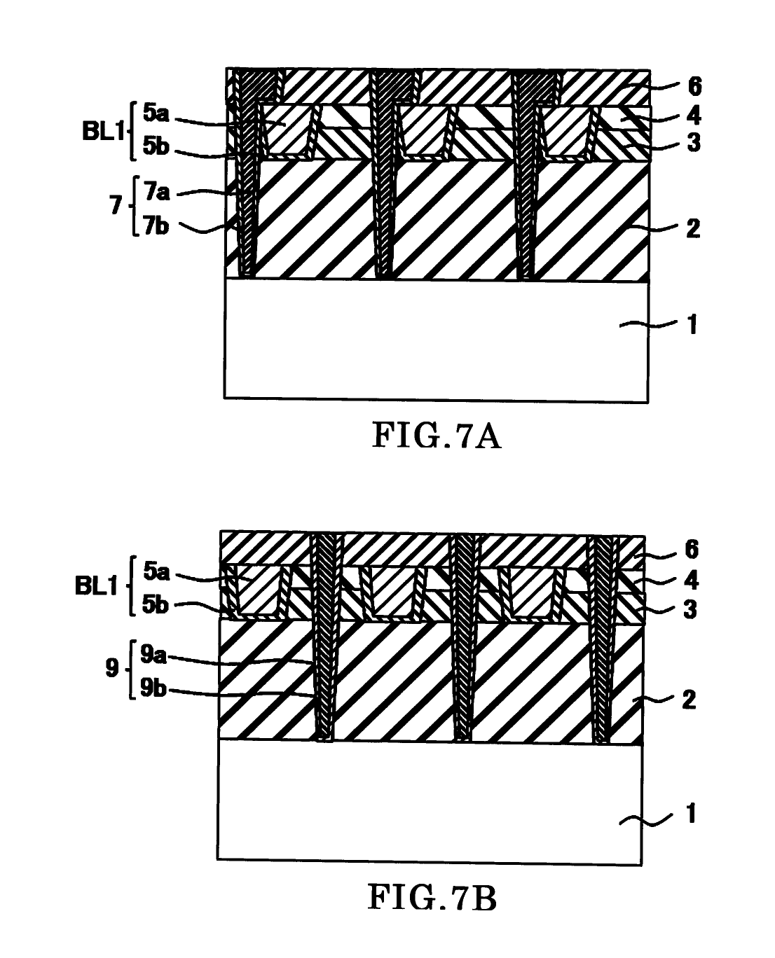

Subsequently, as shown in FIGS. 7A and 7B, the barrier metal film 7b is formed on the inner surfaces of the first contact holes CH1, and the barrier metal film 9b is formed on the inner surfaces of the second contact holes CH2. For both the barrier metal films 7b and 9b, a Ti/TiN stacked film is used, for example.

Then, the contact plug layer 7a is formed on the barrier metal film 7b, and the contact plug layer 9a is formed on the barrier metal film 9b. Each of the contact plug layer 7a and the contact plug layer 9a is a tungsten film formed by CVD, for example.

Thereafter, the tungsten film and the Ti/TiN stacked film on the second stopper film 6 are polished by CMP, whereby the first contact plugs 7 and the second contact plugs 9 are collectively formed in the first contact holes CH1 and the second contact holes CH2, respectively.

When having a tapered shape, the first bit lines BL1 may serve as masks during the formation of the first contact holes CH1, thereby possibly blocking the etching of portions of the first stopper film 3 and the second interlayer insulating film 4 in contact with the side surfaces of the first bit lines BL1. For this reason, the shape of each first wiring trench 12, i.e. the shape of each first bit line BL1 should desirably be square, instead of being tapered.

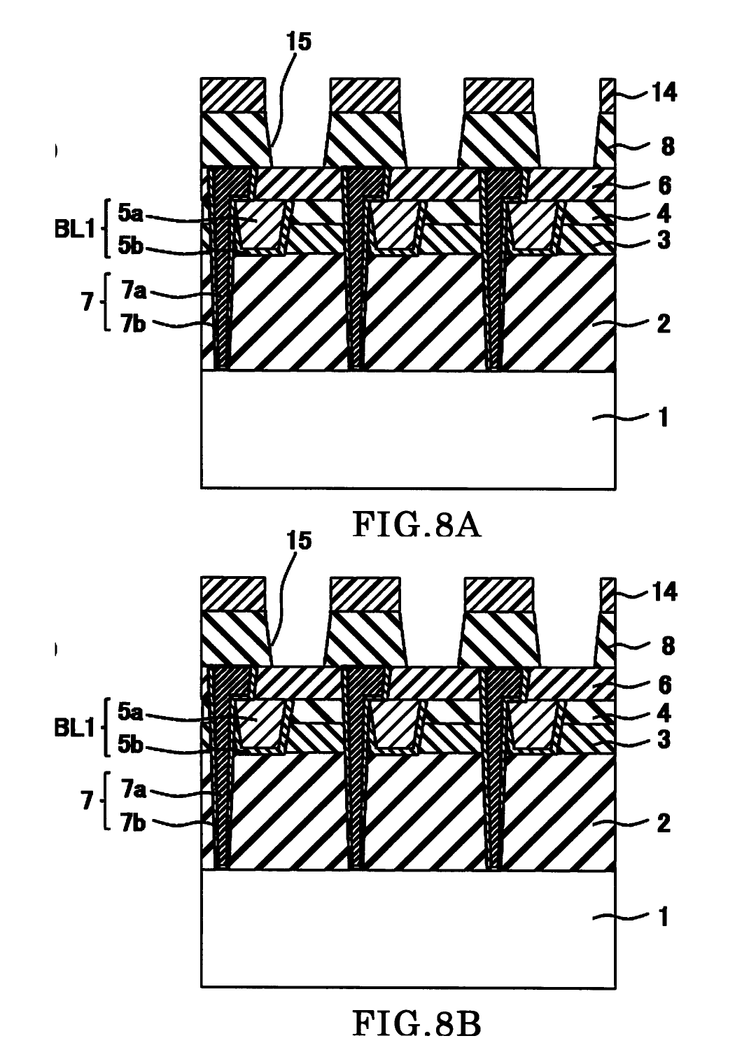

Subsequently, as shown in FIGS. 8A and 8B, a TEOS film for example is formed as the third interlayer insulating film 8 on the first contact plugs 7, and the second contact plugs 9, and the second stopper film 6 by CVD.

Then, a photoresist film 14 is formed on the third interlayer insulating film 8. Thereafter, the photoresist film 14 is processed by photolithography to form the second wiring trenches 15 for forming the second bit lines BL2 extending in the first direction. The second wiring trenches 15 are formed such that the top surfaces of the second contact plugs 9 can be exposed therethrough.

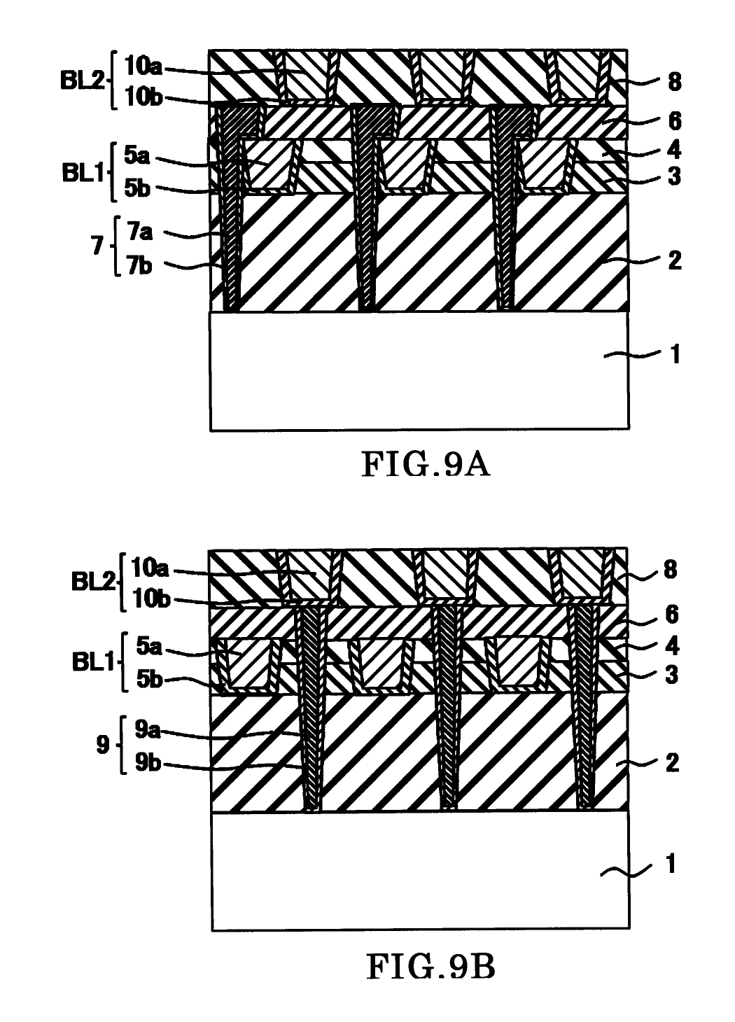

Subsequently, as shown in FIGS. 9A and 9B, after the photoresist film 14 is removed, a Ti/TiN stacked film is formed as the barrier metal film 10b in the second wiring trenches 15, and a Cu wiring is formed as the wiring layer 10a on the barrier metal film 10b. Then, the Cu wiring and the Ti/TiN stacked film on the third interlayer insulating film 8 are polished by CMP, whereby the second bit lines BL2 are formed in the second wiring trenches 15.

By the above procedure, formed is a bit-line arrangement with a two-layer structure in which the first bit lines BL1 are in the lower layer and the second bit lines BL2 are in the upper layer.

As described above, in the embodiment of the present invention, each first contact plug 7 is connected to the side and top surfaces of its corresponding first bit line BL1. Accordingly, the electrical reliability of the first contact plug 7 and the first bit line BL1 can be maintained at a preferable level.

The embodiments are not limited to what has been explained above and may be modified variously. For example, third contact plugs may be provided between the first contact plugs 7 and the semiconductor substrate 1 and between the second contact plugs 9 and the semiconductor substrate 1. The third contact plug is formed by using a tungsten film serving as a contact plug layer and a barrier metal film covering the tungsten film, for example. The third contact plug may be provided in a interlayer insulating film which is a TEOS film, a BPSG film, or a silicon oxide film.

Further, in the embodiment, the contact holes for forming the first contact plugs 7 and the second contact plugs 9 connected to the bit lines in the two-layer structure are formed collectively. Accordingly, the number of exposure steps in the photolithography can be reduced, thereby lowering the cost of the wiring step.

What is claimed is:

1. A semiconductor memory device comprising:
a semiconductor substrate;
a first contact plug and a second contact plug provided on the semiconductor substrate; and
a first bit line being in contact with the first contact plug, and a second bit line provided on the second contact plug,
wherein the first contact plug is in contact with a top surface of the first bit line and is electrically insulated from the second bit line, and
a bottom surface of the second bit line is higher in height than the top surface of the first bit line.

2. The semiconductor memory device according to claim 1, wherein the first contact plug is further in contact with a side surface of the first bit line.

3. The semiconductor memory device according to claim 1, wherein the first bit line is shifted in a second direction in a region where the first bit line and the first contact plug intersect each other.

4. The semiconductor memory device according to claim 3, wherein the first bit line is shifted in the second direction by a distance substantially equal to half a diameter of a top surface of the first contact plug.

5. The semiconductor memory device according to claim 1, wherein
a plurality of the first contact plugs and a plurality of the second contact plugs are each arranged at periodic intervals in the second direction, and
the first contact plugs and the second contact plugs are arranged in a staggered pattern.

6. The semiconductor memory device according to claim 1, wherein
a diameter of a bottom surface of the first contact plug is substantially equal to that of a bottom surface of the second contact plug, and
a diameter of a top surface of the second contact plug is substantially half a diameter of a top surface of the first contact plug.

7. The semiconductor memory device according to claim 1, wherein a cross-sectional shape of the first bit line is substantially rectangular.

8. The semiconductor memory device according to claim 1, wherein a height of the first contact plug is substantially equal to that of the second contact plug.

9. The semiconductor memory device according to claim 1, wherein each of the first bit line and the second bit line is formed of a wiring layer and a barrier metal film covering the wiring layer.

10. The semiconductor memory device according to claim 1, wherein each of the first contact plug and the second contact plug is a tungsten film.

11. The semiconductor memory device according to claim 9, wherein the wiring layer is a Cu layer.

12. A method of fabricating a semiconductor memory device, comprising:
forming a first insulating film on a semiconductor substrate;
forming a second insulating film on the first insulating film;
processing the second insulating film to form a first wiring trench;
forming a first bit line in the first wiring trench;
forming a third insulating film on the second insulating film and the first bit line;
processing the third insulating film, the second insulating film, and the first insulating film to form a first contact hole and a second contact hole and also to expose a top surface of the first bit line through the first contact hole;
burying a first contact plug into the first contact hole, and a second contact plug into the second contact hole;
forming a fourth insulating film on the third insulating film, the first contact plug, and the second contact plug;
processing the fourth insulating film to form a second wiring trench on the second contact plug; and
forming a second bit line in the second wiring trench.

13. The method of fabricating a semiconductor memory device according to claim 12, wherein a side surface of the first bit line is also exposed in the forming of the first contact hole.

14. The method of fabricating a semiconductor memory device according to claim 12, wherein
a plurality of the first contact holes and a plurality of the second contact holes are each formed at periodic intervals in a second direction, and
the first contact plugs and the second contact plugs are formed in a staggered pattern.

15. The method of fabricating a semiconductor memory device according to claim 12, wherein in the forming of the first contact hole, the top surface of the first bit line is exposed by an area substantially equal to one half of a top surface of the first contact plug that is defined by a diameter thereof.

16. The method of fabricating a semiconductor memory device according to claim 12, wherein a height of the first contact hole is substantially equal to that of the second contact hole.

17. The method of fabricating a semiconductor memory device according to claim 12, wherein
the second insulating film is a stacked film in which a first stopper film and an interlayer insulating film are stacked in this order,
the first stopper film has an etch selectivity to the first insulating film,
the third insulating film is a second stopper film, and
the second stopper film has an etch selectivity to the interlayer insulating film.
